(19) United States
(12) Patent Application Publication
(10) Pub. No.: US 2014/0176289 A1
(43) Pub. Date: Jun. 26, 2014

(54) ELECTROMAGNETIC INTERFERENCE FILTER AND METHOD OF MANUFACTURING THE SAME

(71) Applicant: SAMSUNG ELECTRO-MECHANICS CO., LTD., Suwon (KR)

(72) Inventors: Jae Sun WON, Suwon (KR); Seung Ho HAN, Suwon (KR); Jae Gen EOM, Suwon (KR); Hwa Hun CHIN, Suwon (KR); Tae Hoon KIM, Suwon (KR); Seung Wan YU, Suwon (KR)

(73) Assignee: SAMSUNG ELECTRO-MECHANICS CO., LTD.

(21) Appl. No.: 13/920,970

(22) Filed: Jun. 18, 2013

(30) Foreign Application Priority Data
Dec. 21, 2012 (KR) 10-2012-0151472
Mar. 27, 2013 (KR) 10-2013-0032734

(51) Int. Cl. H01F 3/12; H01F 41/02; H03H 3/00

(52) U.S. Cl. CPC H01F 3/12; H03H 3/00; H01F 41/02
USPC 336/215; 29/605

(57) ABSTRACT

There are provided an electromagnetic interference filter and a method of manufacturing the same. The electromagnetic interference filter includes a base core including a first base core and a second base core facing the first base core, a leg core including first and second leg cores disposed between the first base core and the second base core, the first and second leg cores facing each other, a winding coil part including first and second winding coils wound around the first and second leg cores, respectively, and connected to a power supply, the first and second winding coils respectively providing magnetizing inductance and leakage inductance, and a central core disposed between the first and second cores to provide an inductance leakage path between the first and second base cores.

### CROSS-REFERENCE TO RELATED APPLICATIONS

This application claims priority from Korean Patent Application Nos. 10-2012-0151472 filed on Dec. 21, 2012 and 10-2013-0032734 filed on Mar. 27, 2013, in the Korean Intellectual Property Office, the disclosures of which are incorporated herein by reference in their entirety.

### BACKGROUND OF THE INVENTION

1. Field of the Invention

The present invention relates to an electromagnetic interference (EMI) filter capable of being applied to a flat panel display (FPD) and a method of manufacturing the same.

2. Description of the Related Art

In general, in the case of a flat panel display (FPD), a large amount of electromagnetic wave noise may occur due to a switching type power converter, an image board, a semiconductor device, or the like, included therein. In order to suppress the electromagnetic wave noise, an electromagnetic interference (EMI) filter may generally be used.

The electromagnetic interference filter may be used for a switched-mode power supply (SMPS). The SMPS performs a switching operation at a low frequency, which may cause electromagnetic wave noise.

In general, an SMPS included in a flat panel display may include a power quality unit, a power conversion unit, and a load. The power conversion unit may include a rectification unit, a power factor correction (PFC) unit, and a DC/DC type switching converter. When the power conversion unit uses a non-isolated power factor correction (PFC) unit, a DC/DC converter having a topology that may be isolated, such as an LLC (inductor+inductor+capacitor) resonance type converter, a flyback converter, or the like, may be adopted.

In this case, a large amount of electromagnetic interference (EMI) may occur in the DC/DC converter due to a sudden change in current and voltage due to the switching operation, operating of a miniaturized image board and semiconductor device and high speed operations thereof, and the like. As a method of regulating EMI, an EMI filter may be provided in front of the power factor correction unit.

Meanwhile, electromagnetic wave noise may be largely classified into conducted emissions and radiated emissions, each of which is again classified into a differential mode current and a common mode current.

In general, in the case of the common mode current, a large amount of common mode noise may be present therein within a relatively wide bandwidth, and in the case of the differential mode current, a large amount of differential mode noise may be present within a low frequency band. In particular, in the case of the display device subject to power factor correction, a much larger amount of differential mode noise may appear in the low frequency band.

The electromagnetic wave filter applied to the flat panel display with the existing power factor correction circuit may include two common mode chokes (for example, CM choke 1 and CM choke 2) for reducing the common mode noise appearing in large amounts in a low/high frequency and a differential mode choke (for example, DM choke) for reducing the differential mode noise.

In particular, in the case of the flat panel display, as a line filter (for example, CM choke 1, DM choke 2, and DM choke) according to a slim design of a set, in order to implement a shape having a low height, a line filter structure in which both of the primary and secondary coils are wound around a toroidal type core may be applied.

Further, as a capacitor for reducing noise, an X type capacitor for reducing the differential mode noise and a Y type capacitor for reducing the common mode noise may be used.

However, even in the case of using the existing EMI filter, many other filtering devices may be used, which may lead to increases in both size and cost in the implementation thereof.

The following Related Art Document relates to an integrated electromagnetic interference filter and does not disclose technical matters capable of increasing leakage inductance.

### RELATED ART DOCUMENT

Korean Patent Laid-Open Publication No. 2012-0067568

### SUMMARY OF THE INVENTION

An aspect of the present invention provides an electromagnetic interference (EMI) filter capable of increasing leakage inductance and a method of manufacturing the same.

According to an aspect of the present invention, there is provided an electromagnetic interference filter, including: a base core including a first base core and a second base core facing the first base core; a leg core including first and second leg cores disposed between the first base core and the second base core, the first and second leg cores facing each other; a winding coil part including first and second winding coils wound around the first and second leg cores, respectively, and connected to a power supply, the first and second winding coils respectively providing magnetizing inductance and leakage inductance; and a central core disposed between the first and second leg cores to provide an inductance leakage path between the first and second base cores.

According to an aspect of the present invention, there is provided an electromagnetic interference filter, including: a base core including a first base core and a second base core facing the first base core; a leg core including first and second leg cores disposed between the first base core and the second base core, the first and second leg cores facing each other; a bobbin part including first and second bobbins respectively surrounding the first and second leg cores and having a winding region; a winding coil part including first and second winding coils wound around winding regions of the first and second bobbins, respectively, and connected to a power supply, the first and second winding coils respectively providing magnetizing inductance and leakage inductance; and a central core disposed between the first and second cores to provide an inductance leakage path between the first and second base cores.

The central core may be formed to be attached to the first and second base cores.

According to an aspect of the present invention, there is provided an electromagnetic interference filter, including: a base core; a winding coil part including first and second winding coils wound around both sides of the base core and connected to a power supply, the first and second winding coils respectively providing magnetizing inductance and leakage inductance; and a central core disposed between the first and second winding coils to provide an inductance leakage path between the first and second base cores.

The central core may be formed to be attached to the base core.

The central core may be formed of a material different from that of the base core.

A material forming the base core may be a manganese-zinc ferrite alloy and a material forming the central core may be a nickel-zinc ferrite alloy.

According to an aspect of the present invention, there is provided a method of manufacturing an electromagnetic interference filter, including: preparing a base core including a first base core and a second base core facing the first base core and a leg core including first and second leg cores formed to face each other between the first base core and the second base core; forming a bobbin part including first and second bobbins respectively surrounding the first and second leg cores and having a winding region; forming a winding coil part by winding first and second winding coils around the winding regions of the respective first and second bobbins; and forming a central core between the first and second leg cores to provide an inductance leakage path between the first and second base cores.

The central core may be formed of a material different from that of the base core and the leg core.

A material forming the base core and the leg core may be a manganese-zinc ferrite alloy and a material forming the central core may be a nickel-zinc ferrite alloy.

The method of manufacturing an electromagnetic interference filter may further include: connecting a coil end of the winding coil part to a pin of a base structure between the forming of the winding coil part and the forming of the central core.

In the forming of the central core, the central core may be attached to the first and second base cores.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a structural diagram of an electromagnetic interference filter according to an embodiment of the present invention;

FIG. 2 is a structural diagram of an electromagnetic interference filter according to another embodiment of the present invention;

FIG. 3 is a structural diagram of an electromagnetic interference filter according to another embodiment of the present invention;

FIG. 4 is an exploded perspective view of the electromagnetic interference filter shown in FIG. 2;

FIG. 5 is an assembled perspective view of the electromagnetic interference filter shown in FIG. 2;

FIG. 6 is an equivalent circuit diagram of the electromagnetic interference filter according to the embodiment of the present invention;

FIG. 7 is a differential mode current conducting path diagram of the electromagnetic interference filter according to the embodiment of the present invention;

FIG. 8A and FIG. 8B are graphs illustrating a differential mode noise reducing effect of the electromagnetic interference filter according to the embodiment of the present invention;

FIG. 9 is a flow chart illustrating a method of manufacturing an electromagnetic interference filter according to an embodiment of the present invention;

FIG. 10 is a description diagram illustrating a process of preparing abase core and a leg core according to an embodiment of the present invention;

FIG. 11 is a description diagram illustrating a process of forming a bobbin part according to an embodiment of the present invention;

FIG. 12 is a description diagram illustrating a process of forming a winding coil part according to an embodiment of the present invention;

FIG. 13 is a description diagram illustrating a process of forming a central core according to an embodiment of the present invention;

FIG. 14 is a flow chart illustrating a process of connecting coil ends of the winding coil part according to an embodiment of the present invention;

FIG. 15 is a front view and a back view of the electromagnetic interference filter illustrating the process of connecting the coil ends of the winding coil part according to the embodiment of the present invention; and

FIG. 16 is a circuit diagram illustrating an example in which the electromagnetic interference filter according to the embodiment of the present invention is applied to electronic devices.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein.

Rather, these embodiments are provided so that this disclosure will be thorough and complete, and will fully convey the scope of the invention to those skilled in the art.

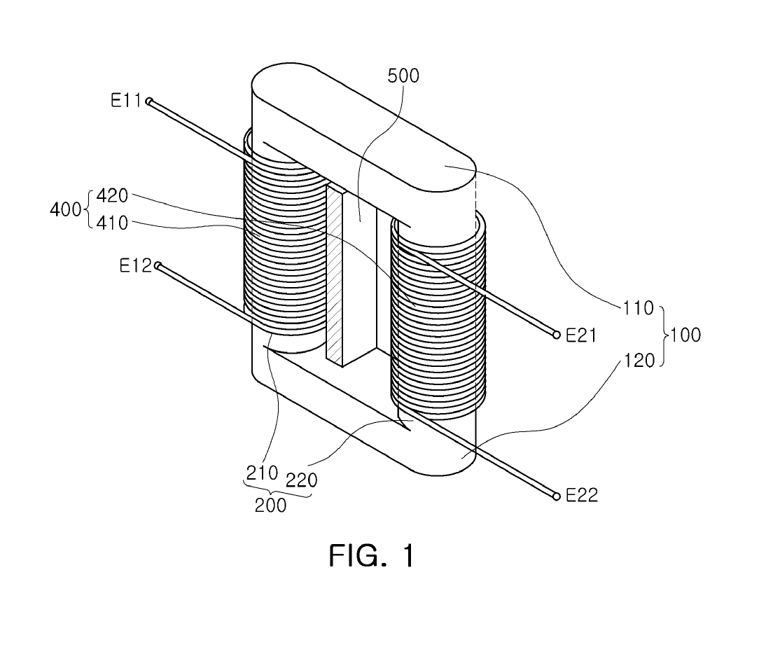

FIG. 1 is a structural diagram of an electromagnetic interference filter according to an embodiment of the present invention.

Referring to FIG. 1, the electromagnetic interference filter according to the embodiment of the present invention may include a base core 100, a leg core 200, a winding coil part 400, and a central core 500.

The base core 100 may include a first base core 110 and a second base core 120 facing the first base core 110.

The leg core 200 may include a first leg core 210 and a second leg core 220 formed between the first base core 110 and the second base core 120. The first leg core 210 and the second leg core 220 may be formed to face each other.

Herein, the reason for representing the base core 100 and the leg core 200 using different terms depends on whether the coil is wound, rather than on a manufacturing method, a material, electrical characteristics, the number of coils provided, or the like. For example, the base core 100 and the leg core 200 may be separately manufactured and then bonded. Alternatively, the base core 100 and the leg core 200 may be integrally manufactured.

The winding coil part 400 may include first and second winding coils 410 and 420 that are wound around the first leg core 210 and the second leg core 220, respectively, and connected to a power supply. In this case, the first and second winding coils 410 and 420 may respectively provide magnetizing inductance and leakage inductance.

Here, the first and second winding coils 410 and 420 may have the same winding ratio, like the general electromagnetic interference filter.

In addition, the first winding coil 410 has first and second coil ends E11 and E12 to be connected to a power supply in the state in which the first winding coil 410 is wound around the first leg core 210. Further, the second winding coil 420 has first and second coil ends E21 and E22 to be connected to a power supply in the state in which the second winding coil 420 is wound around the second leg core 220.

Further, the central core 500 may be disposed between the first leg core 210 and the second leg core 220 to provide an inductance leakage path between the first and second base cores 110 and 120.

In this case, the central core 500 may be attached to the first and second base cores 110 and 120. Here, any attachment method that may provide the inductance leakage path between the first and second base cores 110 and 120 may be used without being limited. For example, bonding, soldering, and the like, may be used, but the present invention is not limited thereto. The central core 500 may provide the inductance leakage path between two attached points of the base core 100.

The central core 500 may be formed so that a separation distance from the first leg core 210 is equal to a separation distance from the second leg core 220.

Further, in order to further increase the leakage inductance, the central core 500 may be formed of a material different from that of the base core 100 and the leg core 200. For example, the material forming the base core 100 and the leg core 200 may be a manganese-zinc (Mn—Zn) ferrite alloy and the material forming the central core 500 may be a nickel-zinc (Ni—Zn) ferrite alloy.

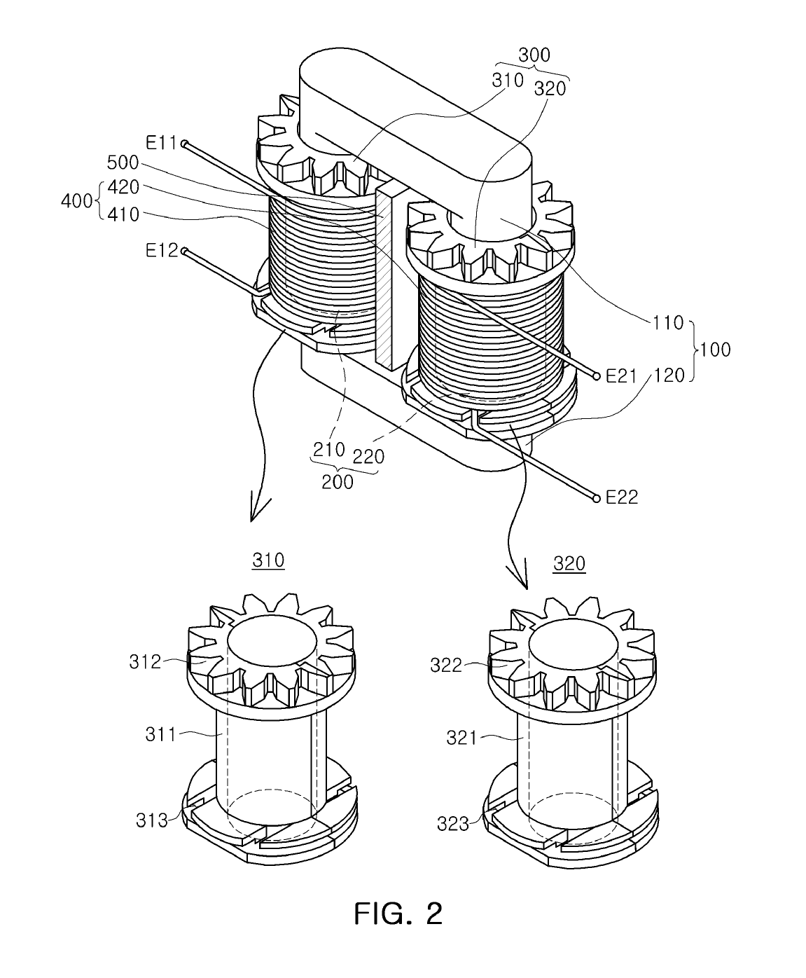

FIG. 2 is a structural diagram of an electromagnetic interference filter according to another embodiment of the present invention.

Referring to FIG. 2, the electromagnetic interference filter may include the base core 100, the leg core 200, the bobbin part 300, the winding coil part 400, and the central core 500.

As described above, a difference between the electromagnetic interference filter according to another embodiment of the present invention illustrated in FIG. 2 and the electromagnetic interference filter according to the embodiment of the present invention is that the electromagnetic interference filter according to the embodiment of the present invention illustrated in FIG. 1 further includes the bobbin part 300 for securing workability and insulation during manufacturing, and the winding coil part 400 is disposed in the bobbin part 300.

Therefore, the base core 100, the leg core 200, and the central core 500 are the same as the electromagnetic interference filter according to the embodiment of the present invention illustrated in FIG. 1 and therefore, overlapping descriptions therebetween may be omitted.

The bobbin part 300 may include first and second bobbins 310 and 320 that surround the first leg core 210 and the second leg core 220, respectively, and that have a winding region. Here, as described below, the bobbin part 300 may facilitate the winding working of the winding coil part 400 and secure insulation between the winding coil part 400 and the core.

Further, the first bobbin 310 may rotate based on the first leg core 210 and may be disposed to surround an outer circumferential surface of the first leg core 210. Further, the second bobbin 320 may rotate based on the second leg core 220 and may be disposed to surround an outer circumferential surface of the second leg core 220.

The first bobbin may include a winding region 311, a gear 312, and a groove 313, while the second bobbin 320 may include a winding region 321, a gear 322, and a groove 323.

In this case, the winding regions 311 and 321 of the respective first and second bobbins 310 and 320 are wound with a portion of the winding coil part 400, and the gears 312 and 322 and the grooves 313 and 323 of the respective first and second bobbins 310 and 320 may be respectively disposed on both ends of the respective winding regions 311 and 321 to facilitate workability.

The winding coil part 400 may include first and second winding coils 410 and 420 that are respectively wound around the winding regions 311 and 321 of the respective first and second bobbins 310 and 320 and connected to a power supply. The first and second winding coils 410 and 420 may respectively provide magnetizing inductance and leakage inductance.

Here, the first and second winding coils 410 and 420 may have the same winding ratio, like the general electromagnetic interference filter.

In addition, the first winding coil 410 may have the first and second coil ends E11 and E12 connected to a power supply in the state in which the first winding coil 410 is wound around the first bobbin 310. Further, the second winding coil 420 may have the first and second coil ends E21 and E22 connected to a power supply in the state in which the second winding coil 420 is wound around the second bobbin 320.

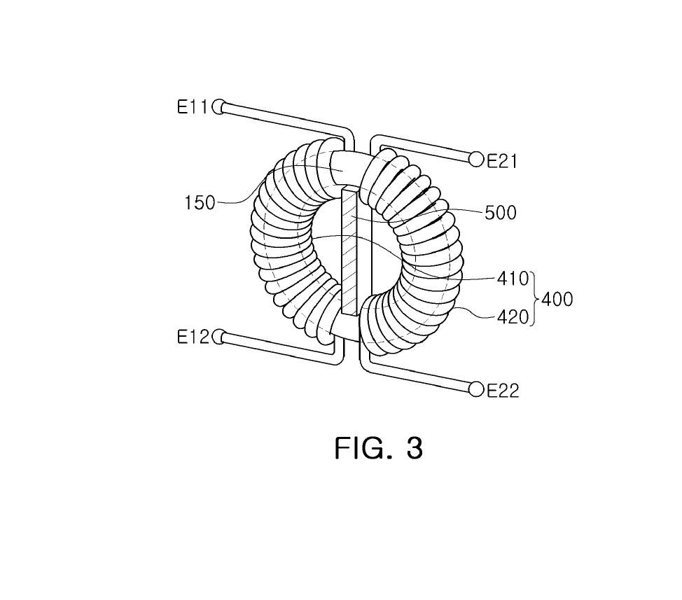

FIG. 3 is a structural diagram of an electromagnetic interference filter according to another embodiment of the present invention.

Referring to FIG. 3, the electromagnetic interference filter according to another embodiment of the present invention may include the base core 150, the winding coil part 400, and the central core 500.

The base core 150 may be manufactured to have an integrated toroidal shape.

The winding coil part 400 may include first and second winding coils 410 and 420 wound around both sides of the base core 150, respectively, and that are connected to a power supply. In this case, the first and second winding coils 410 and 420 may respectively provide magnetizing inductance and leakage inductance.

Here, the first and second winding coils 410 and 420 may have the same winding ratio, like the general electromagnetic interference filter.

In addition, the first winding coil 410 may have the first and second coil ends E11 and E12 connected to a power supply in the state in which the first winding coil 410 is wound around the core 150. Further, the second winding coil 420 may have the first and second coil ends E21 and E22 connected to a power supply in the state in which the second winding coil 420 is wound around the core 150.

Further, the central core 500 may disposed between the base cores 150 to provide the inductance leakage path between the base cores 150.

In this case, the central core 500 may be attached to the base core 150. Here, any attachment method that may provide the inductance leakage path between the base cores 150 may be used without being limited. For example, bonding, soldering, and the like, may be used, but the present invention is not limited thereto. The central core 500 may provide the inductance leakage path between two attached points of the base core 150.

The central core 500 may be formed so that a separation distance from the first winding coil 410 is equal to a separation distance from the second winding coil 420.

Further, in order to further increase the leakage inductance, the central core 500 may be formed of a material different from that of the base core 150. For example, the material forming the base core 150 may be a manganese-zinc (Mn—Zn) ferrite alloy, and the material forming the central core 500 may be a nickel-zinc (Ni—Zn) ferrite alloy.

Meanwhile, referring to FIGS. 1, 2, and 3, the base core may have a quadrangular shape as illustrated in FIGS. 1 and 2 and may have a toroidal shape as illustrated in FIG. 3, but the shape or form thereof is not particularly limited.

Further, in the embodiment illustrated in FIGS. 1 and 2, the base core 100 and the leg core 200 may be integrally formed or may also be assembled and attached after being manufactured separately. That is, the manufacturing method thereof is not particularly limited.

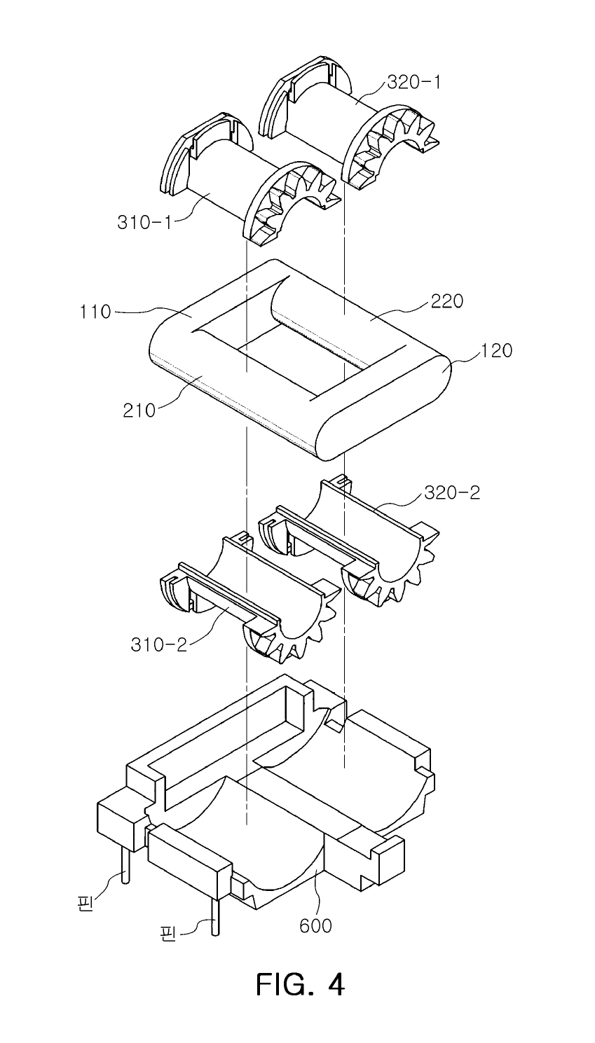

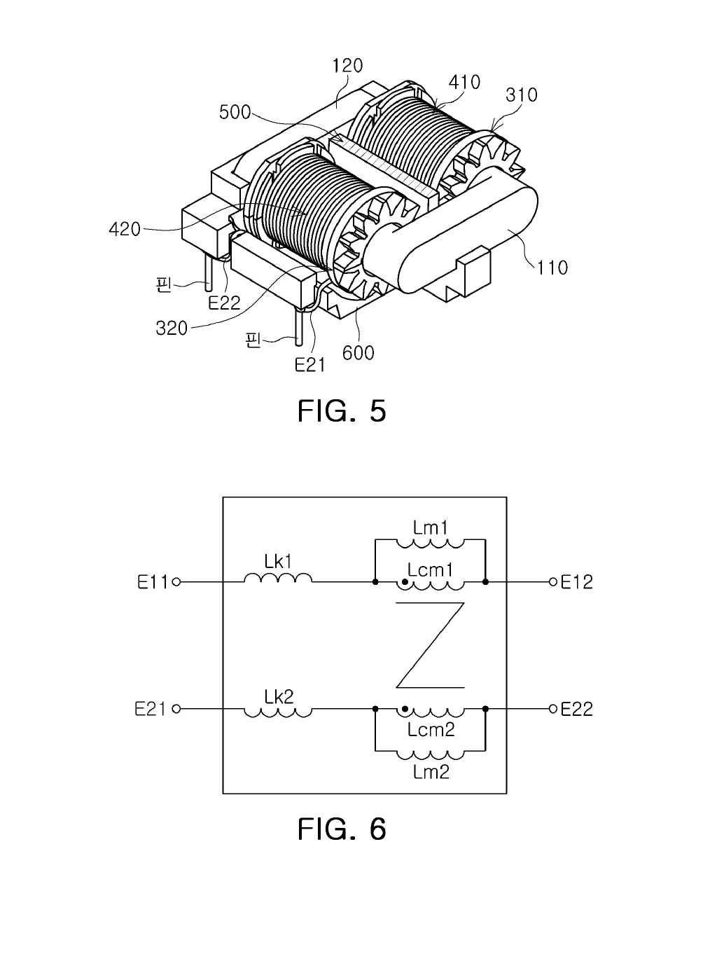

FIG. 4 is an exploded perspective view of the electromagnetic interference filter according to another embodiment of the present invention and FIG. 5 is an assembled perspective view of the electromagnetic interference filter shown in FIG. 4.

The electromagnetic interference filter according to another embodiment of the present invention will be described with reference to FIGS. 4 and 5.

For example, referring to FIG. 4, the first bobbin 310 is manufactured as two pieces of bobbin, 310-1 and 310-2, which may be assembled with the first leg core 210 as illustrated in FIG. 5. Further, referring to FIG. 4, the second bobbin 320 is manufactured as two pieces of bobbin, 320-1 and 320-2, which may be assembled with the second leg core 220 as illustrated in FIG. 5.

Next, the first bobbin 310 and the second bobbin 320 may respectively be wound with the first winding coil 410 and the second winding coil 420.

Next, the central core 500 disposed between the first winding coil 410 and the second winding coil 420 may be attached to the base core 100.

In this case, the base core 100 and the leg core 200 may be assembled in a separate base structure 600. The base structure 600 may be provided with a pin for electrically connecting the winding coil part to the substrate.

As illustrated in FIG. 5, respective coil ends E21 and E22 of the second winding coil 420 may be electrically connected to the pin of the base structure 600. Although not illustrated directly, respective coil ends of the first winding coil 410 may be electrically connected to the pin of the base structure 600 by the same method as the second winding coil 420.

FIG. 6 is an equivalent circuit diagram of the electromagnetic interference filter according to the embodiment of the present invention.

Referring to FIGS. 5 and 6, in the electromagnetic interference filter according to the embodiment of the present invention, the first winding coil 410 may be represented by a first common mode choke Lcm1 between the first and second coil ends E11 and E12. The second winding coil 420 may be represented by a second common mode choke Lcm2 between the third and fourth coil ends E21 and E22.

In addition, first and second magnetizing inductances Lm1 and Lm2 appear in respective first and second common mode chokes Lcm1 and Lcm2 in parallel.

Further, an inductance leakage magnetic flux formed between the first and second winding coils 410 and 420 may be represented by first and second leakage inductances Lk1 and Lk2. The first and second leakage inductances Lk1 and Lk2 may be increased due to the inductance leakage path that is provided by the central core 500.

Meanwhile, the first and second leakage inductances Lk1 and Lk2 may be increased due to the central core 500. For example, in connection with the existing electromagnetic interference filter and the electromagnetic interference filter according to the embodiment of the present invention, comparison results of respective leakage inductances based on an experiment in which 1 kHz and 100 kHz of the low frequency of the differential mode are respectively represented in the following Table 1.

TABLE 1

| | | |
|---|---|---|
| Experimental | Related Art | Present Invention |

| Frequency | [1 kHz] | [100 kHz] | [1 kHz] | [100 kHz] |
|---|---|---|---|---|
| 1 | 144 μH | 141 μH | 256 μH | 253 μH |
| 2 | 145 μH | 141 μH | 261 μH | 257 μH |
| 3 | 144 μH | 140 μH | 216 μH | 213 μH |
| 4 | 144 μH | 141 μH | 218 μH | 214 μH |

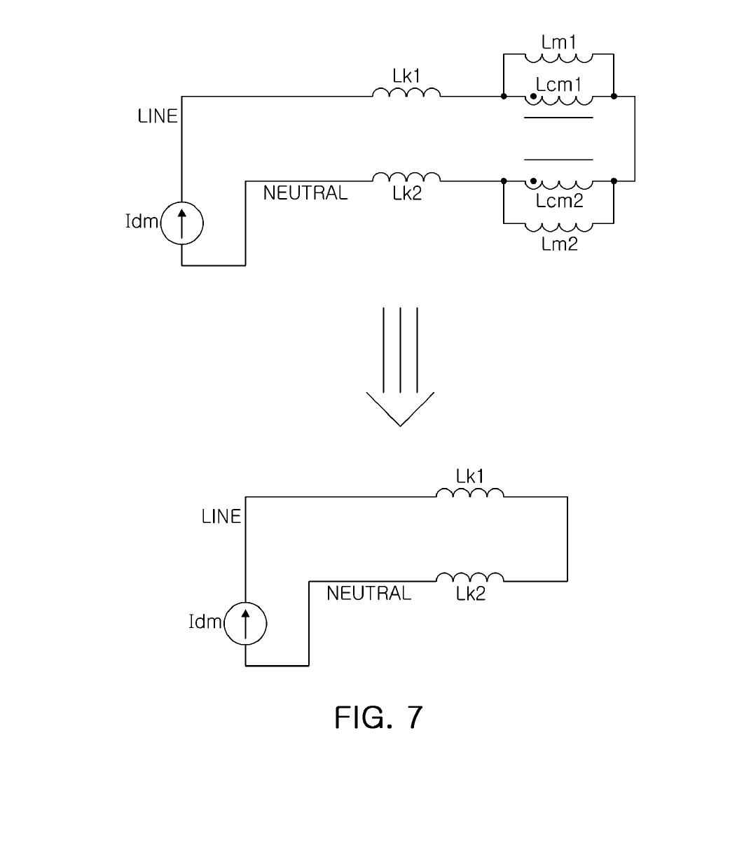

FIG. 7 is a differential mode current conducting path diagram of the electromagnetic interference filter according to the embodiment of the present invention.

Referring to FIG. 7, an equivalent circuit (see the upper portion of FIG. 7) in the differential mode of the electromagnetic interference filter according to the embodiment of the present invention is the same as the equivalent circuit illustrated in FIG. 6.

In this case, in the viewpoint of low frequency noise in the differential mode, an equivalent circuit having the first and second leakage inductances Lk1 and Lk2 may be illustrated, as illustrated in the lower portion of FIG. 7.

As described above, referring to the above Table 1 and FIG. 7, it can be appreciated that the first and second leakage inductances Lk1 and Lk2 may be approximately two times as high as that of the related art, and the first and second leakage inductances Lk1 and Lk2 may perform the filter function on the differential mode noise to improve the low frequency removing effect of the differential mode. In other words, the number of devices for removing the low frequency of the differential mode may be reduced to correspond thereto.

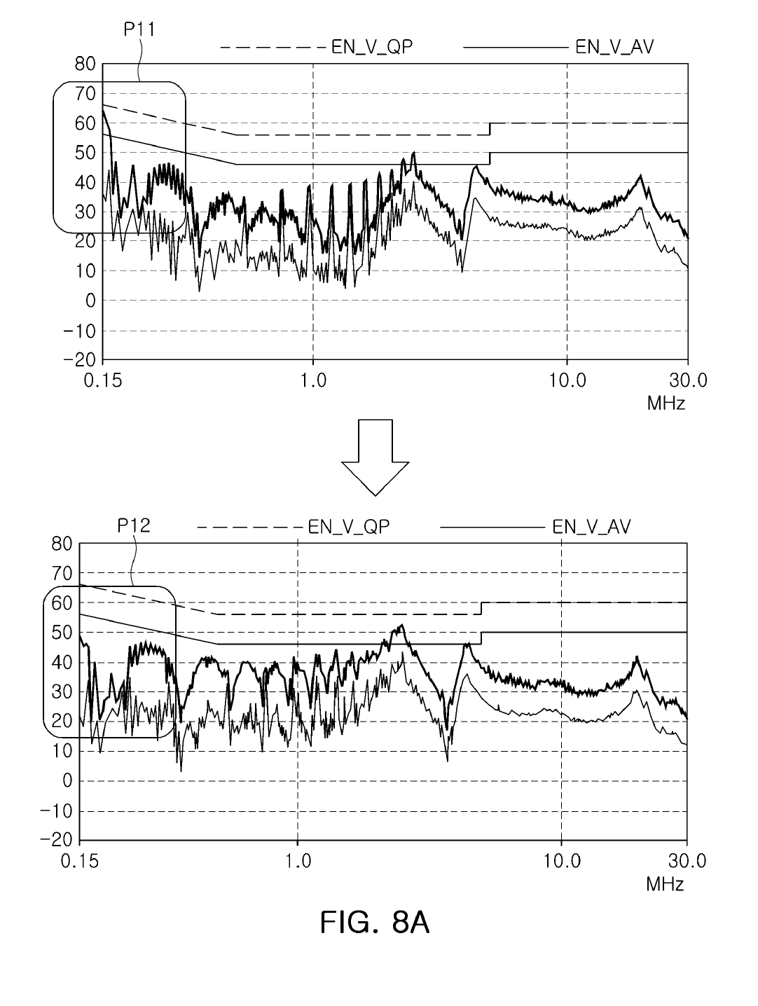

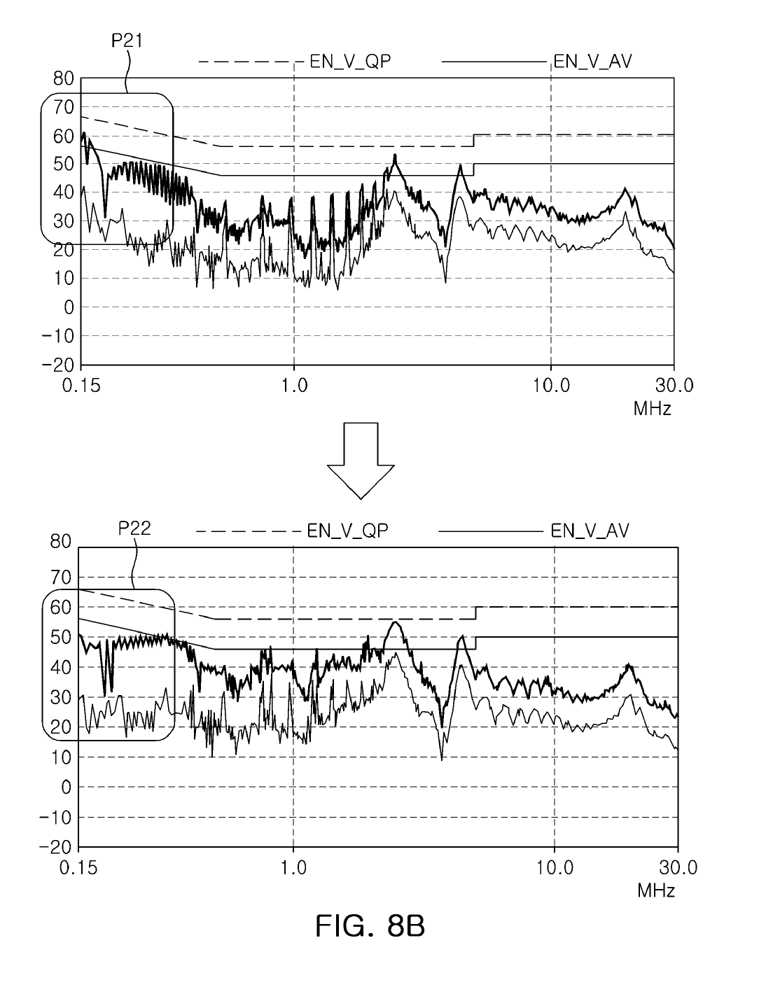

FIG. 8A and FIG. 8B are graphs illustrating a differential mode noise reducing effect of the electromagnetic interference filter according to the embodiment of the present invention.

FIG. 8A is graphs illustrating the low frequency reducing effect in the differential mode for 110 Vac of 60 Hz. Referring to the graphs, it can be appreciated that the low frequency characteristic (portion P12) of the electromagnetic interference filter according to the embodiment of the present invention is more improved than the low frequency characteristic (portion P11) of the electromagnetic interference filter according to the related art.

FIG. 8B is graphs illustrating the low frequency reducing effect in the differential mode for 230 Vac of 60 Hz. Referring to the graphs, it can be appreciated that the low frequency characteristics (portion P22) of the electromagnetic interference filter according to the embodiment of the present invention are more improved than the low frequency characteristics (portion P21) of the electromagnetic interference filter according to the related art.

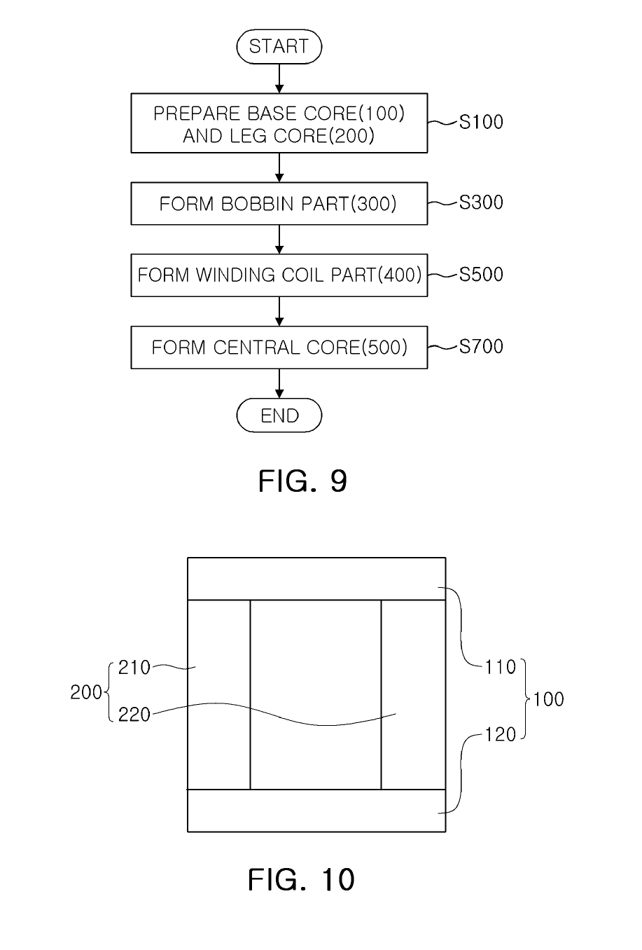

FIG. 9 is a flow chart illustrating a method of manufacturing an electromagnetic interference filter according to an embodiment of the present invention. FIG. 10 is a description diagram illustrating a process of preparing a base core and a leg core according to an embodiment of the present invention.

Referring to FIGS. 1 to 10, in S100, the base core 100 and the leg core 200 may be prepared.

As described above, the base core 100 may include the first base core 110 and a second base core 120 facing the first base core 110.

The leg core 200 may include the a first leg core 210 and a second leg core 220 formed to face each other between the first base core 110 and the second base core 120.

In this case, the core may have a quadrangular shape or a toroidal shape, but the shape or form thereof is not particularly limited. Further, the base core 100 and the leg core 200 may be integrally formed or may be assembled and attached by being manufactured separately. That is, the manufacturing method thereof is not particularly limited.

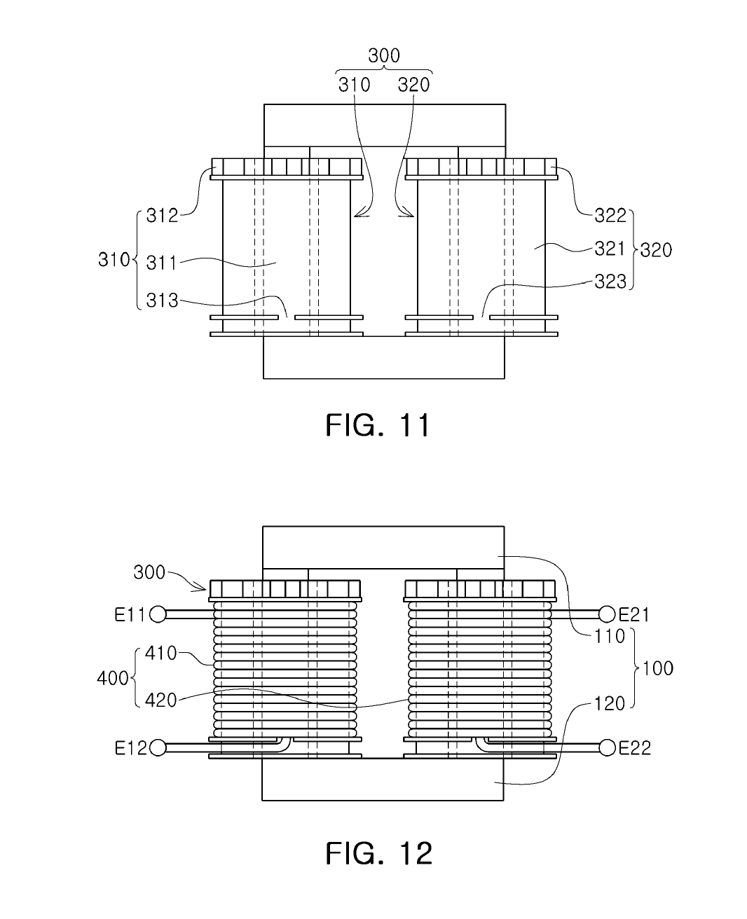

FIG. 11 is a description diagram illustrating a process of forming a bobbin part according to an embodiment of the present invention.

Referring to FIGS. 1 to 11, in S300, the bobbin part 300 may be formed.

The bobbin part 300 may include the first and second bobbins 310 and 320 that surround the first leg core 210 and the second leg core 220, respectively, and that have a winding region. For example, as illustrated in FIGS. 4 and 5, the first bobbin 310 is manufactured as two pieces of bobbin, 310-1 and 310-2, which may be assembled with the first leg core 210, as illustrated in FIG. 5. Further, referring to FIG. 4, the second bobbin 320 is manufactured as two pieces of bobbin, 320-1 and 320-2, which may be assembled with the second leg core 220, as illustrated in FIG. 5.

In addition, the first bobbin 310 may include the winding region 311, the gear 312, and the groove 313. Here, the gear 312 and the groove 313 may respectively be formed on both ends of the winding region of the first bobbin 310 to facilitate winding workability. In addition, the second bobbin 320 may include the winding region 321, the gear 322, and the groove 323. Here, the gear 322 and the groove 323 may be formed on both ends of the winding region of the second bobbin 320 to facilitate winding workability.

In the forming of the bobbin part 300 (S300), the first and second winding coils 410 and 420 may be formed to have the same winding ratio.

FIG. 12 is a description diagram illustrating a process of forming a winding coil part according to an embodiment of the present invention.

Referring to FIGS. 1 to 12, in 5500, the winding coil part 400 may be formed.

The winding coil part 400 may include the first and second winding coils 410 and 420 that are respectively wound around the winding regions of the respective first and second bobbins 310 and 320.

Here, the first winding coil 410 has first and second coil ends E11 and E12 to be connected to a power supply in the state in which the first winding coil 410 is wound around the first leg core 210. Further, the second winding coil 420 may have the first and second coil ends E21 and E22 to be connected to a power supply in the state in which the second winding coil 420 is wound around the second leg coil 220.

Describing the process of forming the winding coil part according to the embodiment of the present invention with reference to FIGS. 1 to 12, in the forming of the winding coil part 400 (S500), the first bobbin 310 may include the gear 312 and the groove 313 that are respectively formed on both ends of the winding region of the first bobbin 310, and the second bobbin 320 may include the gear 322 and the groove 323 that are respectively formed on both ends of the winding region of the second bobbin 320.

Next, in the forming of the winding coil part 400 (S500), the first and second winding coils 410 and 420 may respectively be wound the winding regions 311 and 321 of the respective first and second bobbins 310 and 320 by using the grooves 313 and 323 and the gears 312 and 322 that are formed on both ends of the respective first and second bobbins 310 and 320.

As described above, the first bobbin 310 may include the winding region 311, the gear 312, and the groove 313. Here, the gear 312 and the groove 313 may be respectively formed on both ends of the respective bobbins. In addition, the second bobbin 320 may include the winding region 321, the gear 322, and the groove 323. Here, the gear 322 and the groove 323 may be respectively formed on both ends of the second bobbin 320.

For example, the coil of one of the first coil end E11 or the second coil end E12 of the first winding coil 410 is locked to the groove 313 formed in one end of the first bobbin 310 to rotate the gear 312 formed on one end of the first bobbin 310, engaging with an external transmission gear, such that the first winding coil 410 may be wound around the winding region 311 of the first bobbin 310.

In the same manner, the coil of one of the third coil end E21 and the fourth coil end E22 of the second winding coil 420 is locked to the groove 323 formed in one end of the second bobbin 320 to rotate the gear 322 formed on one end of the second bobbin 320, engaging with an external transmission gear, such that the second winding coil 420 may be wound around the winding region 321 of the second bobbin 320.

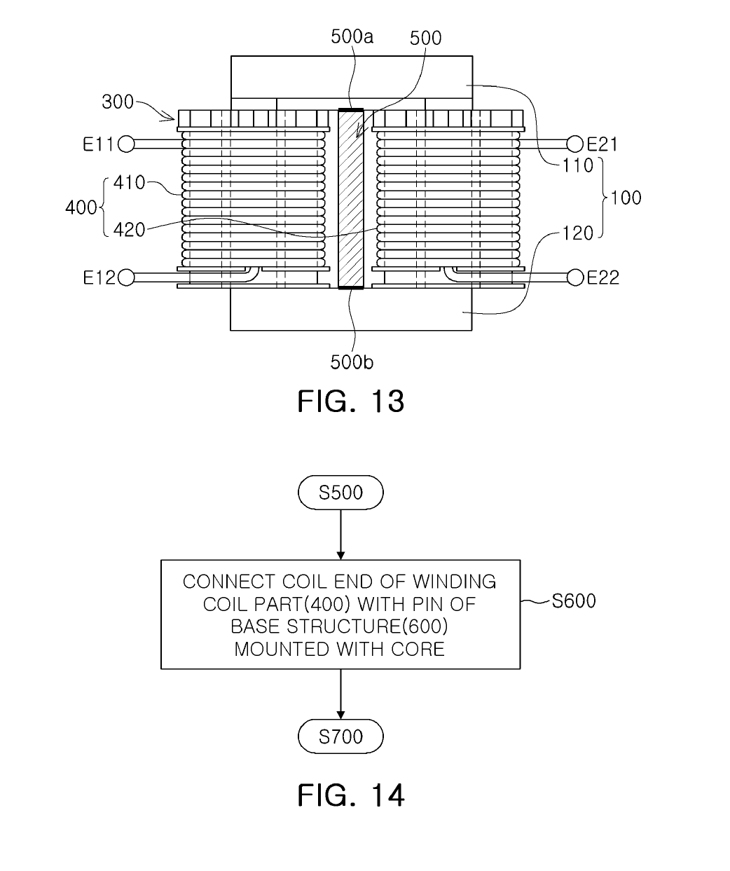

FIG. 13 is a description diagram illustrating a process of forming a central core according to an embodiment of the present invention.

Referring to FIGS. 1 to 13, in 5700, the central core 500 may be formed.

For example, the central core 500 may be disposed between the first leg core 210 and the second leg core 220. Further, the central core 500 may be attached to the first and second base cores 110 and 120. For example, the central core 500 may be attached to the first and second base cores 110 and 120 by soldering 500a and 500b, but the present invention is not limited thereto.

In this case, the central core 500 may be formed so that a separation distance from the first leg core 210 is equal to a separation distance from the second leg core 220.

Here, in order to further increase the leakage inductance of the electromagnetic interference filter, the central core 500 may be formed of a material different from that of the base core 100 and the leg core 200. For example, the material forming the base core 100 and the leg core 200 may be a manganese-zinc (Mn—Zn) ferrite alloy. The material forming the central core 500 may be a nickel-zinc ferrite alloy.

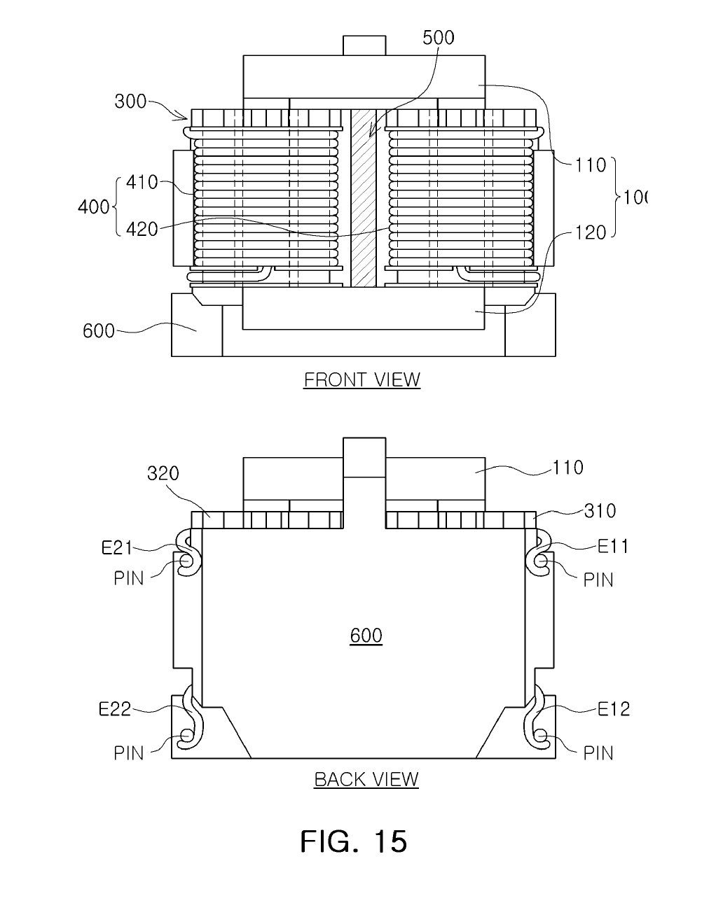

FIG. 14 is a flow chart illustrating a process of connecting coil ends of the winding coil part according to an embodiment of the present invention; FIG. 15 is a front view and a back view of the electromagnetic interference filter illustrating the process of connecting the coil ends of the winding coil part according to the embodiment of the present invention.

Referring to FIG. 14, the method of manufacturing an electromagnetic interference filter according to the embodiment of the present invention may further include connecting the coil end of the winding coil part to the pin of the base structure 600 (S600) between the forming of the winding coil part 400 (S500) and the forming of the central core 500 (S700).

In S600, the coil ends E11, E12, E21, and E22 of the first and second winding coils 410 and 420 may be electrically connected to the pin of the base structure 600.

Referring to FIGS. 14 and 15, in the connecting of the coil ends E11, E12, E21, and E22 (S600), the coil ends E11, E12, E21, and E22 of the respective first and second winding coils 410 and 420 may be electrically connected by the pin formed on the base structure 600 through the soldering or the like.

Here, the pin of the base structure 600 may be connected to the power supply apparatus of the substrate on which the electromagnetic interference filter according to the embodiment of the present invention is mounted.

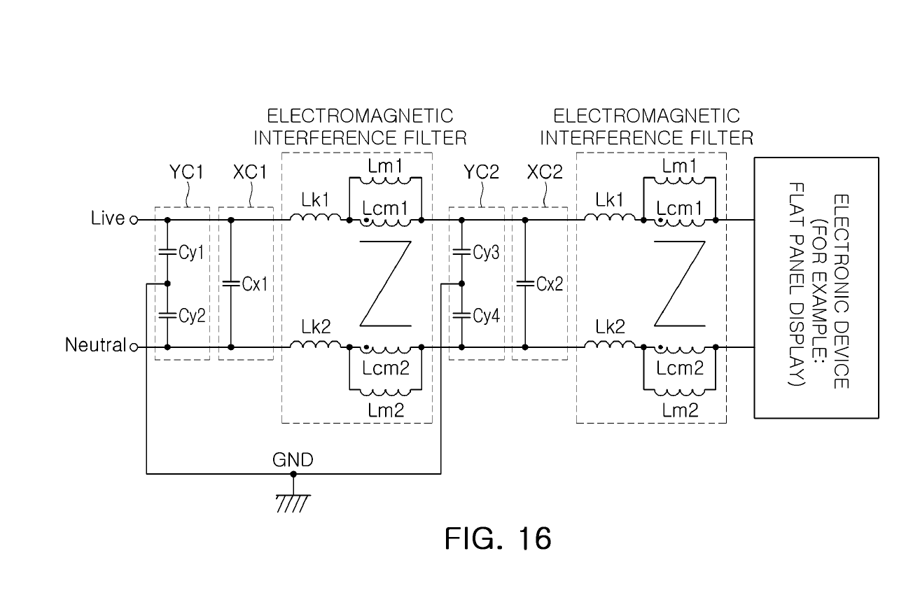

FIG. 16 illustrates an example of a circuit in which the electromagnetic interference filter according to the embodiment of the present invention is applied to electronic devices.

As illustrated in FIG. 16, when the electromagnetic interference filter according to the embodiment of the present invention is applied to electronic devices, the electromagnetic interference filter may be mounted between an input terminal (live and neutral) and the electronic device and configured in like manner to Y capacitors YC1 and YC2 and X capacitors XC1 and XC2.

For example, the electromagnetic interference filter according to the embodiment of the present invention may be applied to the flat panel display. In this case, the number of devices for reducing the common mode and differential mode noise and the size thereof may be reduced due to the electromagnetic interference filter in which the functions of the common mode choke and the differential mode choke are integrated. Therefore, the design time may be shortened and the development cost may be reduced.

In addition, the common mode and differential mode chokes according to the related art are manufactured manually, and therefore the productivity may be degraded; however, the automatic winding may be achieved at the time of manufacturing, and thus the productivity is increased, the manufacturing cost is reduced, and the number of devices is reduced, such that the electromagnetic interference filter may be miniaturized, thereby increasing the space availability.

As set forth above, according to the embodiment of the present invention, the EMI filter may provide the magnetizing inductance and the leakage inductance, in particular, may increase the leakage inductance.

While the present invention has been shown and described in connection with the embodiments, it will be apparent to those skilled in the art that modifications and variations can be made without departing from the spirit and scope of the invention as defined by the appended claims.

What is claimed is:

1. An electromagnetic interference filter, comprising:
a base core including a first base core and a second base core facing the first base core;
a leg core including first and second leg cores disposed between the first base core and the second base core, the first and second leg cores facing each other;
a winding coil part including first and second winding coils wound around the first and second leg cores, respectively, and connected to a power supply, the first and second winding coils respectively providing magnetizing inductance and leakage inductance; and
a central core disposed between the first and second leg cores to provide an inductance leakage path between the first and second base cores.

2. The electromagnetic interference filter of claim 1, wherein the central core is formed of a material different from that of the base core and the leg core.

3. The electromagnetic interference filter of claim 1, wherein the central core is formed to be attached to the first and second base cores.

4. The electromagnetic interference filter of claim 1, wherein the central core is formed so that a separation distance from the first leg core is equal to a separation distance from the second leg core.

5. The electromagnetic interference filter of claim 1, wherein a material forming the base core and the leg core is a manganese-zinc ferrite alloy.

6. The electromagnetic interference filter of claim 1, wherein a material forming the central core is a nickel-zinc ferrite alloy.

7. The electromagnetic interference filter of claim 1, wherein the base core and the leg core have one of a quadrangular shape and a toroidal shape.

8. An electromagnetic interference filter, comprising:
a base core including a first base core and a second base core facing the first base core;
a leg core including first and second leg cores disposed between the first base core and the second base core, the first and second leg cores facing each other;
a bobbin part including first and second bobbins respectively surrounding the first and second leg cores and having a winding region;
a winding coil part including first and second winding coils wound around winding regions of the first and second bobbins, respectively, and connected to a power supply, the first and second winding coils respectively providing magnetizing inductance and leakage inductance; and
a central core disposed between the first and second leg cores to provide an inductance leakage path between the first and second base cores.

9. The electromagnetic interference filter of claim 8, wherein the central core is formed of a material different from that of the base core and the leg core.

10. The electromagnetic interference filter of claim 8, wherein the central core is formed to be attached to the first and second base cores.

11. The electromagnetic interference filter of claim 8, wherein the central core is formed so that a separation distance from the first leg core is equal to a separation distance from the second leg core.

12. The electromagnetic interference filter of claim 8, wherein a material forming the base core and the leg core is a manganese-zinc ferrite alloy.

13. The electromagnetic interference filter of claim 8, wherein a material forming the central core is a nickel-zinc ferrite alloy.

14. The electromagnetic interference filter of claim 8, wherein the base core and the leg core have one of a quadrangular shape and a toroidal shape.

15. An electromagnetic interference filter, comprising:
a base core;
a winding coil part including first and second winding coils wound around both sides of the base core and connected to a power supply, the first and second winding coils respectively providing magnetizing inductance and leakage inductance; and
a central core disposed between the first and second winding coils to provide an inductance leakage path between the first and second base cores.

16. The electromagnetic interference filter of claim 15, wherein the central core is formed of a material different from that of the base core.

17. The electromagnetic interference filter of claim 15, wherein the central core is formed to be attached to the base core.

18. The electromagnetic interference filter of claim 15, wherein the central core is formed so that separation distances from both sides of the base cores are equal to each other.

19. The electromagnetic interference filter of claim 15, wherein a material forming the base core is a manganese-zinc ferrite alloy.

20. The electromagnetic interference filter of claim 15, wherein a material forming the central core is a nickel-zinc ferrite alloy.

21. The electromagnetic interference filter of claim 15, wherein the base core and the leg core have one of a quadrangular shape and a toroidal shape.

22. A method of manufacturing an electromagnetic interference filter, comprising:
preparing a base core including a first base core and a second base core facing the first base core and a leg core including first and second leg cores formed to face each other between the first base core and the second base core;
forming a bobbin part including first and second bobbins respectively surrounding the first and second leg cores and having a winding region;
forming a winding coil part by winding first and second winding coils around the winding regions of the respective first and second bobbins; and
forming a central core between the first and second leg cores to provide an inductance leakage path between the first and second base cores.

23. The method of claim 22, wherein the central core is formed of a material different from that of the base core and the leg core.

24. The method of claim 22, wherein in the forming of the central core, the central core is attached to the first and second base cores.

25. The method of claim 22, wherein the central core is formed so that a separation distance from the first leg core is equal to a separation distance from the second leg core.

26. The method of claim 22, wherein a material forming the base core and the leg core is a manganese-zinc ferrite alloy.

27. The method of claim 22, wherein a material forming the central core is a nickel-zinc ferrite alloy.

28. The method of claim 22, wherein the base core and the leg core have one of a quadrangular shape and a toroidal shape.

29. The method of claim 22, further comprising:
connecting a coil end of the winding coil part to a pin of a base structure between the forming of the winding coil part and the forming of the central core.

30. The method of claim 22, wherein the first bobbin includes a gear and a groove respectively disposed on both ends of the winding region of the first bobbin, and the second bobbin includes a gear and a groove respectively disposed on both ends of the winding region of the second bobbin.

31. The method of claim 30, wherein in the forming of the winding coil part, the first and second winding coils are respectively wound around the winding region of the respective first and second bobbins by using the groove and the gear formed on both ends of the winding region of the respective first and second bobbins.
